(19) United States
(12) Patent Application Publication
(10) Pub. No.: US 2007/0004177 A1
(43) Pub. Date: Jan. 4, 2007

(54) Wafer processing method

(76) Inventors: Masaru Nakamura, Tokyo (JP); Takatoshi Masuda, Tokyo (JP)

Correspondence Address: WENDEROTH, LIND & PONACK, L.L.P., 2033 K STREET N. W., SUITE 800, WASHINGTON, DC, 20006-1021, US

(21) Appl. No.: 11/447,130

(22) Filed: Jun. 6, 2006

(30) Foreign Application Priority Data
Jun. 29, 2005 (JP) 2005-189540

(51) Int. Cl. H01L 21/00

(52) U.S. Cl. 438/460

(57) ABSTRACT

To prevent cracks from appearing in a wafer when tape is affixed to or peeled off a wafer in a state where the streets break easily preventing damage to or deterioration in the quality of the devices, in a wafer processing method including steps of performing a pre-process on a wafer from a front surface side or from a rear surface side of the wafer to separate the wafer along the streets, affixing adhesive tape to the front surface or to the rear surface of the pre-processed wafer, and performing a predetermined process on the wafer in a state where the adhesive tape is affixed to the wafer, a pressure roller is rolled over the adhesive tape in a direction not parallel to the streets so as to press the adhesive tape onto the front surface or the rear surface of the wafer in the adhesive tape affixing step.

### BACKGROUND OF THE INVENTION

1. Field of the Invention

The present invention relates to a technology for separating a wafer into individual devices after preparatory processing of the wafer.

2. Related Art

Conventionally, a wafer on the surface of which a plurality of devices such as ICs, LSIs and the like are formed by partitioning with streets and the wafer is separated along the streets so as to divide the wafer into individual devices that are then used in a variety of electronic devices.

Although a wafer can be divided into devices by cutting into the streets with a high-speed rotary cutting blade, with methods that use a cutting blade to divide the wafer into devices the devices are sometimes chipped or cracked. Consequently, a technology called Dicing Before Grinding (DBG) has been developed, in which grooves of a depth corresponding to the thickness of the completed devices are formed along the streets on a wafer, after which a protective adhesive tape is affixed to the front surface of the wafer, the wafer is held on a holding table by the adhesive tape side, ground from the rear surface to the thickness of the completed devices and divided into the individual devices (for example, JP-A-11-40520).

In addition, a technology has been proposed in which adhesive tape is affixed to the rear surface of the wafer after laser beam of a wavelength that can penetrate the wafer is collected within the streets so as to form brittle areas, and the adhesive tape is stretched so as to separate the wafer into individual devices along the lines (for example, JP-A-2002-192370). With such methods that use lasers, if the laser is directed onto the front surface of the wafer there is a risk that the devices formed thereon might fuse together, and therefore it is preferable that the laser beam be directed onto the wafer from the rear surface of the wafer. Where the laser is directed onto the rear surface of the wafer, adhesive tape for protecting the devices is affixed to the front surface of the wafer prior to the irradiation of the laser beam. After the laser beam has been irradiated, adhesive tape is affixed to the rear surface of the wafer and the device protection adhesive tape is peeled off the front surface of the wafer.

In all the methods described above, the affixing of the adhesive tape to the wafer is typically achieved by rolling a pressure roller over the adhesive tape in the direction of the streets to press the adhesive tape onto the wafer (as in, for example, JP-A-2003-7649)

However, where grooves or brittle regions are formed in the wafer beneath the streets, the wafer breaks easily along the streets. Consequently, when pressure from a pressure roller is used to apply adhesive tape to the front surface or to the rear surface of the wafer, cracks caused by the force of that pressure do appear in directions other than along the streets, which damage or otherwise degrade the quality of the devices produced from that wafer.

In addition, in the method involving affixing adhesive tape to the rear surface of the wafer and directing a laser onto the rear surface of the streets so as to form brittle regions inside the wafer under the streets, cracks do appear when removing the protective tape after forming the brittle regions in the wafer under the streets in directions not along the streets, which damage or otherwise degrade the quality of the devices produced from that wafer.

### SUMMARY OF THE INVENTION

Accordingly, the wafer processing method of the present invention is proposed to prevent cracks from appearing in a wafer when tape is affixed to or peeled off a wafer in a state in which the streets break easily so as to prevent damage to or deterioration in the quality of the devices formed from that wafer.

To achieve the above-described objects, the present invention provides a wafer processing method including a pre-processing step of performing a pre-process on a wafer on a front surface of which a plurality of devices is formed by partitioning with streets from the front surface side of the wafer or from a rear surface side of the wafer so as to separate the wafer along the streets, an adhesive tape affixing step of affixing adhesive tape to the front surface or to the rear surface of the pre-processed wafer, and a processing step of performing a predetermined process on the wafer in a state in which the adhesive tape is affixed to the wafer, wherein in the adhesive tape affixing step a pressure roller is rolled over the adhesive tape in a direction not parallel to the streets so as to press the adhesive tape onto the front surface or the rear surface of the wafer.

In the pre-processing step, if a laser irradiates the wafer from the rear surface to form brittle portions inside the wafer under the streets, then in the processing step an external force is applied to the streets and the wafer is divided into individual devices.

Where protective tape is affixed to the front surface of the wafer prior to the pre-processing step, the protective tape is peeled off the front surface of the wafer in a direction not parallel to the streets after adhesive tape is affixed to the rear surface of the wafer in the adhesive tape affixing step.

Where grooves of a depth corresponding to the thickness of the finished devices are formed along the streets in the pre-processing step, adhesive tape is affixed to the front surface of the wafer in the adhesive tape affixing step and the rear surface of the wafer is ground so as to expose the grooves from the rear surface side, after which the wafer is divided into individual devices in the processing step.

Preferably, the direction not parallel to the streets is a direction at a 45-degree angle to the streets.

In the present invention, when adhesive tape is affixed to the front surface or to the rear surface of a wafer pre-processed with streets, the adhesive tape is affixed to the front or rear surface of the wafer by moving the pressure roller over the adhesive tape affixed to the surface in a direction that is not parallel to any of the streets, and thus cracks do not appear in the wafer in direction other than along the streets. Therefore, there is no damage to or deterioration in the quality of the devices formed from that wafer.

In addition, when protective tape is affixed to the front surface of the wafer prior to the pre-processing surface, removing the protective tape in a direction not parallel to the streets enables cracks in the wafer in directions other than the streets to be prevented from occurring during removal of the protective tape, thus preventing damage to or deterioration in the quality of the devices formed from that wafer.

In addition, by setting the direction in which the pressure roller is moved during affixing of the adhesive tape or by setting the direction in which the adhesive tape is peeled off at a 45-degree angle to the streets, damage to or deterioration in the quality of the devices formed from that wafer can be more securely prevented.

Other objects, features and advantages of the present invention will be apparent from the following description when taken in conjunction with the accompanying drawings, in which like reference characters designate the same or similar parts throughout the figures thereof.

### BRIEF DESCRIPTION OF THE DRAWINGS

FIG. 1 is a perspective view showing a wafer and a protective tape;

FIG. 2 is a perspective view showing a first example of a pre-processing step according to the present invention;

FIG. 3 is a sectional view showing a first example of an adhesive tape affixing step according to the present invention;

FIG. 4 is a perspective view showing the first example of an adhesive tape affixing step;

FIG. 5 is a sectional view showing a state of removal of the protective tape according to the present invention;

FIG. 6 is a perspective view showing a state of removal of the protective tape;

FIG. 7 is a perspective view showing a first example of a processing step according to the present invention;

FIG. 8 is a perspective view showing a second example of a pre-processing step according to the present invention;

FIG. 9 is a sectional view showing a second example of an adhesive tape affixing step according to the present invention;

FIG. 10 is a perspective view showing the first example of an adhesive tape affixing step; and

FIG. 11 is a sectional view showing a first example of a processing step according to the present invention.

### DETAILED DESCRIPTION OF THE PREFERRED EMBODIMENTS

A detailed description will now be given of a preferred embodiment of the present invention, with reference to the accompanying drawings.

The front surface W1 of a wafer W shown in FIG. 1 is partitioned by longitudinal streets S1 and latitudinal streets S2 and a plurality of devices D is formed. To separate the wafer W along these streets S1, S2 so as to divide the wafer into individual devices D, first, protective tape for protecting the devices is affixed to the front surface W1 of the wafer W.

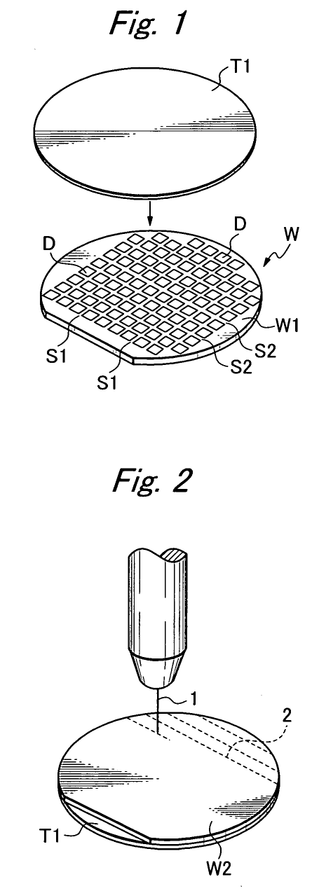

Next, as shown in FIG. 2, the wafer W, to the front surface W1 of which protective tape T1 is affixed, is turned upside down. Then, the streets S1, S2 on the front surface side of the wafer W are detected by an infrared camera from a rear surface W2 side of the wafer W and laser beam 1 of a wavelength capable of penetrating the wafer, for example 1064 mn, is irradiated onto the rear surface of the wafer W. At this time, the laser beam 1 is concentrated on the interior of the wafer W under the streets S1, S2, altering the interior of the wafer under the streets S1, S2 so as to form brittle regions 2 therein. The step of forming brittle regions inside the wafer W is a preliminary process performed in order later to divide the wafer W into individual devices D, and is called a pre-process step.

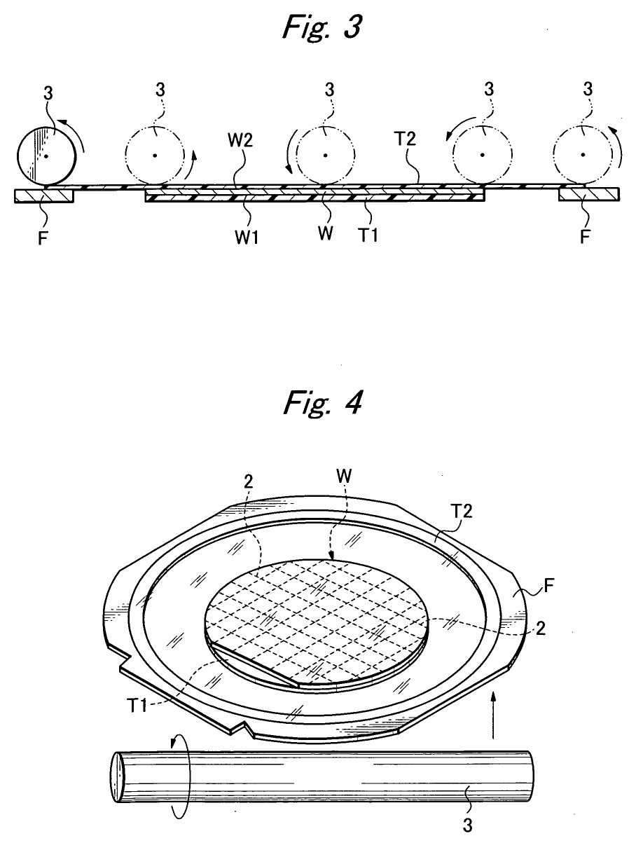

Next, as shown in FIG. 3, with the rear surface W2 of the wafer W2 still facing up, the wafer W is set on a ring-shaped frame F opening, adhesive tape T2 is affixed to the top of the frame F and the rear surface W2 of the wafer W, and a pressure roller 3 is rolled over the tops of the wafer W and the frame F so that the adhesive tape T2 forms the wafer W and the frame F into a single unit (an adhesive tape affixing step).

At this time, as shown in FIG. 4, the direction of movement of the pressure roller 3 is a direction that is not parallel to either the longitudinal streets S1 or the latitudinal streets S2. For example, it is preferable that the direction of movement of the pressure roller 3 be at a 45-degree angle to the longitudinal streets S1 as well as to the latitudinal streets S2.

Thus, by moving the pressure roller 3 in a direction that is parallel to neither the longitudinal streets S1 nor the latitudinal streets S2 as described above, even if brittle regions are formed beneath the streets, because the direction in which pressure is exerted by the pressure roller 3 is different from the directions in which the brittle regions are formed, the wafer neither breaks nor cracks, and therefore there is no damage to or deterioration in the quality of the devices formed from that wafer. In particular, damage to or degradation of the quality of the wafer can be more securely prevented when the direction of movement of the pressure roller 3 is at a 45-degree angle to the longitudinal streets S1 and the latitudinal streets S2.

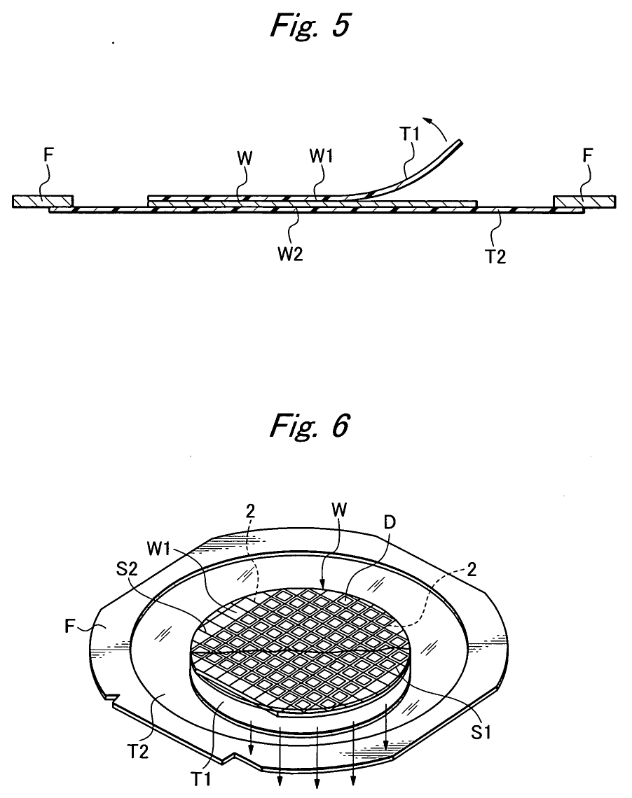

After the adhesive tape T2 is affixed to the rear surface W2 of the wafer W and the frame F as described above, as shown in FIG. 5 the protective tape T1 is peeled off the front surface W1 of the wafer W. At this time, as shown in FIG. 6, the direction in which the protective tape T1 is peeled off the front surface W1 of the wafer W is not parallel to either the longitudinal streets S1 or the latitudinal streets S2. For example, it is preferable that the direction in which the protective tape T1 is pulled be at a 45-degree angle to the longitudinal streets S1 as well as to the latitudinal streets S2.

Thus, by pulling the protective tape T1 and peeling it off in a direction that is parallel to neither the longitudinal streets S1 nor the latitudinal streets S2 as described above, even if brittle regions are formed beneath the streets, because the direction in which the tensile force works is different from the directions in which the brittle regions are oriented, the wafer neither breaks nor cracks, and therefore there is no damage to or deterioration in the quality of the devices formed from that wafer. In particular, damage to or deterioration in the quality of the wafer can be more securely prevented when the direction in which the protective tape T1 is peeled off the front surface W1 of the wafer W is at a 45-degree angle to the longitudinal streets S1 and to the latitudinal streets S2.

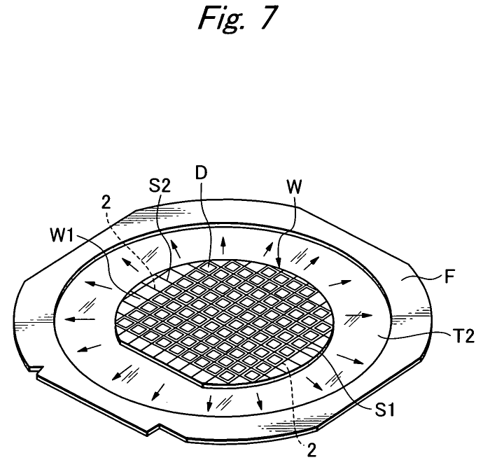

After the removal of the protective tape T1, as shown in FIG. 7 the protective tape T2 is stretched outward toward the outer periphery of the frame F, exerting an external force on the longitudinal streets S1 and the latitudinal streets S2. When that is accomplished, because brittle regions are formed inside the wafer W under the longitudinal streets S1 and the latitudinal streets S2, the wafer W is separated along the longitudinal streets S1 and the latitudinal streets S2 and divided into the individual devices D (a processing step). The method of exerting external force on the longitudinal streets S1 and the latitudinal streets S2 described above is not limited to that of stretching the adhesive tape T2 toward the outer periphery.

It should be noted that, in the example described above, the protective tape T1 is affixed to the front surface W1 of the wafer W because the laser beam is irradiated onto the wafer W from the rear surface W2 side. If the laser beam irradiates the wafer W from the front surface W1 side in the pre-processing step, the protective tape T1 is affixed to the rear surface W2 of the wafer W. In this case, after the pre-processing step the adhesive tape 2 is affixed to the rear surface W2 of the wafer W.

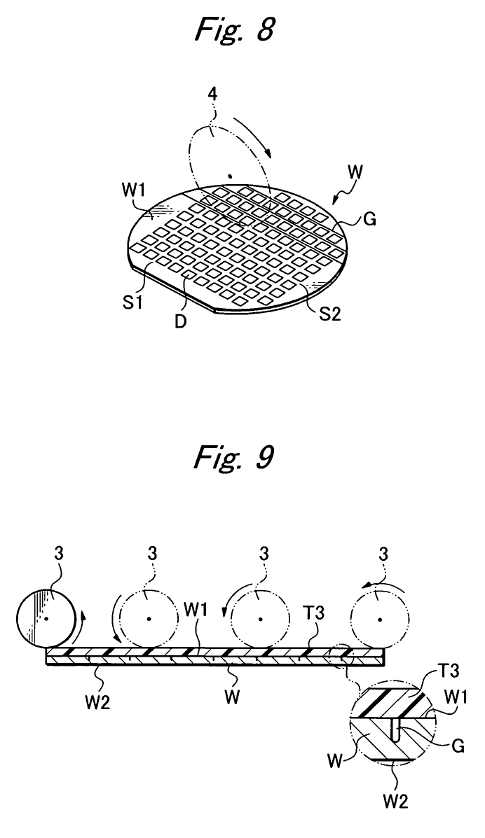

Next, a description is given of an example in which the present invention is adapted to so-called Dicing Before Grinding (DBG). As shown in FIG. 8, a plurality of devices D is formed on the front surface W1 of the wafer W by partitioning with longitudinal streets S1 and latitudinal streets S2. Then, initially, the wafer W is cut along the streets S1, S2 with a high-speed rotary cutting blade 4 to form longitudinal and latitudinal grooves G of a depth corresponding to the thickness of the finished devices D (the pre-processing step).

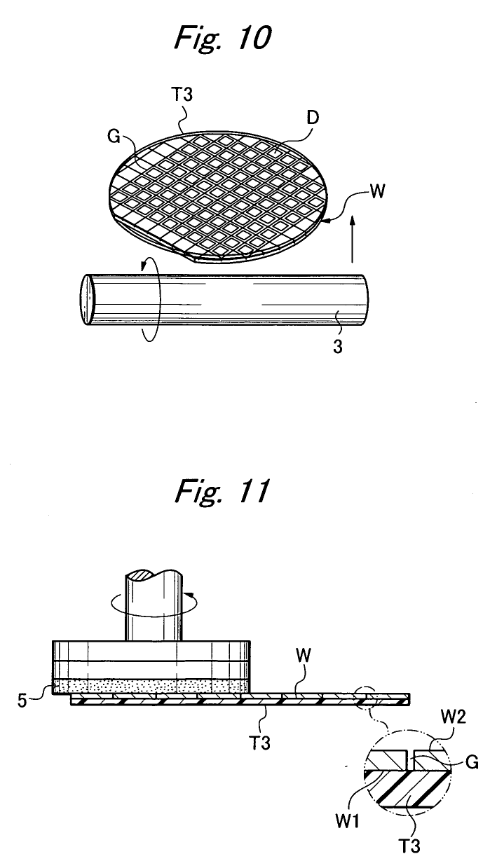

Next, as shown in FIG. 9, adhesive tape T3 is laid down on the front surface W1 of the wafer W in which the groves G are formed, and pressed and affixed thereto by the movement of the pressure roller 3 (the adhesive tape affixing step). At this time, as shown in FIG. 10, the direction of movement of the pressure roller 3 is not parallel to either the longitudinal streets S1 or the latitudinal streets S2. For example, it is preferable that the direction of movement of the pressure roller 3 be at a 45-degree angle to the longitudinal streets S1 as well as to the latitudinal streets S2.

Thus, by moving the pressure roller 3 in a direction that is parallel to neither the longitudinal streets S1 nor the latitudinal streets S2 as described above, even if grooves G are formed along the streets, because the direction in which pressure is exerted by the pressure roller 3 is different from the directions in which the grooves G are formed, the wafer W neither breaks nor cracks, and therefore there is no damage to or deterioration in the quality of the devices formed from that wafer. In particular, damage to or deterioration in the quality of the wafer can be more securely prevented when the direction of movement of the pressure roller 3 is at a 45-degree angle to the longitudinal streets S1 and the latitudinal streets S2.

For a wafer W in the front surface W1 of which the grooves G are formed and to such front surface W1 the adhesive tape T3 is affixed, the rear surface W2 is ground by contacting a rotary grindstone 5 against the rear surface W2 of the wafer W as shown in FIG. 11. Then, when the grooves G appear in the rear surface W2, the wafer is separated along the streets S1, S2 and divided into the individual devices D (the processing step).

As many apparently widely different embodiments and variations of the present invention can be made without departing from the spirit and scope thereof, It is to be understood that the invention is not limited to the specific embodiments thereof and described herein, except as defined in the appended claims.

1. A wafer processing method comprising:
a pre-processing step of performing a pre-process on a wafer on a front surface of which a plurality of devices is formed by partitioning with streets from the front surface side of the wafer or from a rear surface side of the wafer so as to separate the wafer along the streets;
an adhesive tape affixing step of affixing adhesive tape to the front surface or to the rear surface of the pre-processed wafer; and
a processing step of performing a predetermined process on the wafer in a state in which the adhesive tape is affixed to the wafer,
wherein in the adhesive tape affixing step a pressure roller is rolled over the adhesive tape in a direction not parallel to the streets so as to press the adhesive tape onto the front surface or the rear surface of the wafer.

2. A wafer processing method according to claim 1, wherein:
in the pre-processing step, a laser irradiates the wafer from the rear surface to form brittle portions beneath the streets; and
in the processing step, external force is applied to the streets and the wafer is divided into individual devices.

3. A wafer processing method according to claim 2, wherein:
protective tape is affixed to the front surface of the wafer prior to the pre-processing step; and
in the adhesive tape affixing step, after adhesive tape is affixed to the rear surface of the wafer, the protective tape is peeled off the front surface of the wafer in a direction not parallel to the streets.

4. A wafer processing method according to claim 1, wherein:
in the pre-processing step grooves of a depth corresponding to the thickness of the finished devices are formed along the streets;
in the adhesive tape affixing step, adhesive tape is affixed to the front surface of the wafer; and
in the processing step, the rear surface of the wafer is ground so as to expose the grooves from the rear surface side and the wafer is divided into individual devices.

5. A wafer processing method according to claim 1, wherein the direction not parallel to the streets is at a 45-degree angle to the streets.

6. A wafer processing method according to claim 2, wherein the direction not parallel to the streets is at a 45-degree angle to the streets.

7. A wafer processing method according to claim 3, wherein the direction not parallel to the streets is at a 45-degree angle to the streets.

8. A wafer processing method according to claim 4, wherein the direction not parallel to the streets is at a 45-degree angle to the streets.
